(19) United States
(12) Patent Application Publication
(10) Pub. No.: US 2006/0065195 A1
(43) Pub. Date: Mar. 30, 2006

(54) Microwave plasma generating device

(75) Inventor: Masaaki Nagatsu, Shizuoka (JP)

Correspondence Address: VENABLE LLP, P.O. BOX 34385, WASHINGTON, DC, 20045-9998, US

(73) Assignee: HAMAMATSU FOUNDATION FOR SCIENCE AND TECHNOLOGY PR, SHIZUOKA (JP)

(21) Appl. No.: 10/539,279

(22) PCT Filed: Nov. 26, 2003
(86) PCT No.: PCT/JP03/15088

§ 371 Date: Jun. 16, 2005

(30) Foreign Application Priority Data
Dec. 20, 2002 (JP) 2002-369983

(51) Int. Cl. C23C 16/00; H01L 21/306

(52) U.S. Cl. 118/723 MW; 156/345.1

(57) ABSTRACT

A microwave plasma generator is provided in which a gas in a vacuum vessel is directly excited by an evanescent wave from a microwave resonator disposed in the vessel without using an ECR system. The microwave plasma generator of the present invention includes a microwave source to generate an excitation microwave, a discharge gas source, a plasma generation vacuum vessel to be supplied with a gas from the discharge gas source, a coaxial waveguide to introduce the excitation microwave into the vessel, and a parallel plate launcher disposed in the vessel. In the parallel plate launcher, a resonant cavity is constructed from a first conductor plate connected to an outer conductor of the coaxial waveguide, a dielectric plate, and a second conductor plate connected to a central conductor of the coaxial waveguide and provided with a plurality of openings to emit evanescent microwaves into the vacuum vessel.

### BACKGROUND OF THE INVENTION

1. Field of the Invention

The present invention relates to a plasma generator in which a carrier gas in a vacuum chamber is excited by only a microwave so as to generate plasma.

2. Description of the Related Art

An electron cyclotron resonance (ECR) plasma device is known. Since a magnetic field is used for this type of plasma device, a magnetic field generator is required. Therefore, an entire device tends to become large, and there is a problem in that a large plasma space cannot be ensured. Furthermore, an industrial desire to generate a high density plasma in a large space is not satisfied since the operation pressure (gas partial pressure) must be regulated at a relatively low pressure (a high degree of vacuum).

With respect to the above-described electron cyclotron resonance (ECR) plasma device and the like, a plasma generator in which a vacuum vessel to be supplied with a carrier gas is excited through a quartz window of the vessel by an antenna or the like disposed in the outside is known. This device generates plasma by an electromagnetic field on the surface of the boundary between the quartz window and the carrier gas in the vessel. As an area of a plasma generation region is increased, a quartz window pane having a large area and a large thickness is required. Since the gas is subjected to the action of the electromagnetic field passing through the quartz window pane, the influence is decreased correspondingly.

Furthermore, a device in which a microwave launcher is disposed in the above-described vacuum vessel and a microwave is directly introduced into the vessel is known. Japanese Unexamined Patent Application Publication No. H01-184921, Japanese Unexamined Patent Application Publication No. H01-184922, Japanese Unexamined Patent Application Publication No. H01-184923, and Japanese Unexamined Patent Application Publication No. H03-191072 disclose inventions related to plasma generators of the type in which a microwave launcher is disposed in a vacuum vessel so as to excite a carrier gas in the vessel. However, in each configuration, the microwave is not directly supplied from a microwave supply device into the vessel, but the microwave is supplied through a dielectric transmission window or the like. As for the horn antenna excitation, streamer-like excitation is effected, thereby there is a problem in that wide-range homogeneous plasma excitation becomes difficult.

### SUMMARY OF THE INVENTION

It is an object of the present invention to provide a plasma generator in which a gas in a vacuum vessel is directly excited by an evanescent wave from a microwave resonator disposed in the above-described vessel without using an ECR system.

In order to achieve the above-described object, a microwave plasma generator according to a first aspect of the present invention includes a microwave source to generate an excitation microwave, a discharge gas source, a plasma generation vacuum vessel to be supplied with a gas from the above-described discharge gas source, a coaxial waveguide to introduce the excitation microwave into the above-described vessel, and a parallel plate launcher in which a resonant cavity is constructed from a first conductor plate connected to an outer conductor of the above-described coaxial waveguide, a dielectric plate, and a second conductor plate connected to a central conductor of the above-described coaxial waveguide and provided with a plurality of openings to emit evanescent microwaves into the above-described vacuum vessel.

A microwave plasma generator according to a second aspect of the present invention is the microwave plasma generator according to the first aspect, wherein the above-described coaxial waveguide is hermetically coupled to the above-described vacuum vessel and supports the above-described launcher, a support device to support a work is disposed at the position facing the second conductor plate of the above-described launcher, and a relative distance between the above-described support device and the above-described launcher is adjustable.

A microwave plasma generator according to a third aspect of the present invention is the microwave plasma generator according to the first aspect, wherein the above-described vacuum vessel may be a cylindrical vessel, the above-described coaxial waveguide may be moved along the center line of the above-described vessel, and the outline of the first conductor plate of the above-described launcher may be slightly smaller than the inner diameter of the above-described vessel.

A microwave plasma generator according to a fourth aspect of the present invention is the microwave plasma generator according to the first aspect, wherein a cylindrical portion extending in the direction of the above-described second conductor plate may be disposed on the perimeter of the first conductor plate of the above-described launcher, and a microwave emission gap may be disposed between the bottom end edge of the above-described cylindrical portion and the perimeter of the above-described second conductor plate.

A microwave plasma generator according to a fifth aspect of the present invention is the microwave plasma generator according to the first aspect, wherein an output to pulse-modulate the above-described microwave source may be generated by a microwave source driving device, and intermittent driving may be effected.

The microwave excitation plasma can be efficiently generated without using an ECR system. The microwave is directly supplied into the vessel from the electrode of the launcher without passing through the dielectric plate, thereby the plasma can be efficiently generated. The position of the above-described launcher can be adjusted, and a high density plasma space can be voluntarily formed.

### BRIEF DESCRIPTION OF THE DRAWINGS

FIG. 1 is a sectional view of a key portion of a microwave plasma generator according to an embodiment of the present invention.

FIG. 2 is a magnified sectional view of a launcher portion in the above-described embodiment.

FIG. 3 is a magnified diagram of a part of a second conductor plate of the above-described launcher.

FIG. 4 is a plan view of the microwave plasma generator according to the embodiment of the present invention.

### DESCRIPTION OF THE PREFERRED EMBODIMENTS

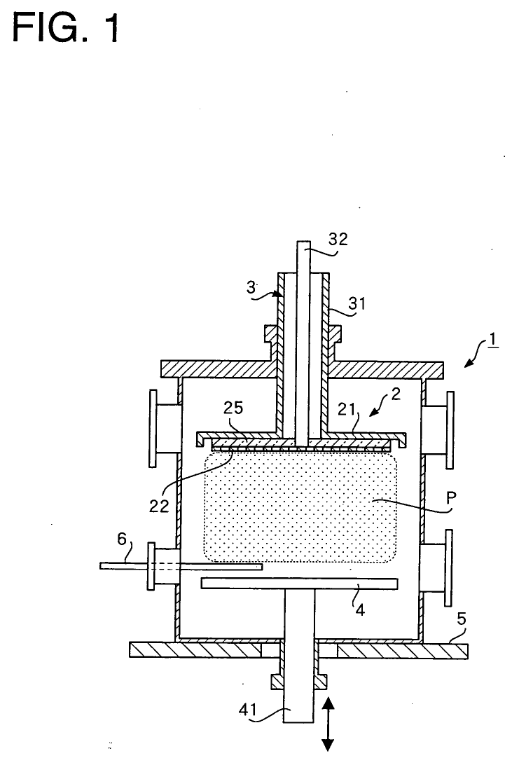

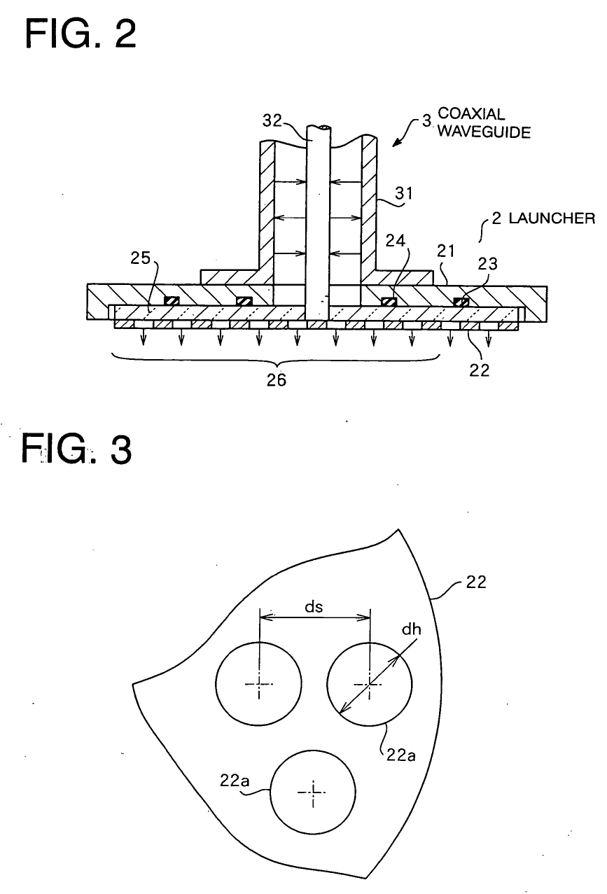

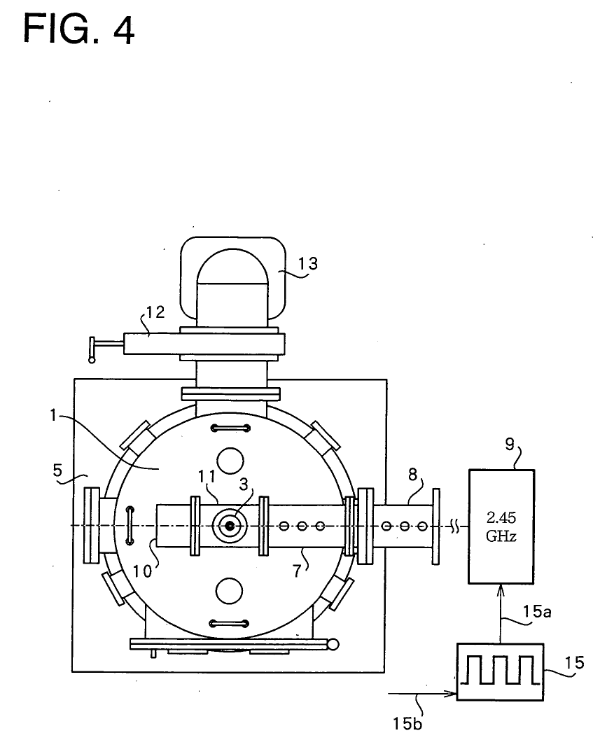

A device according to an embodiment of the present invention will be described below with reference to the drawings. FIG. 1 is a sectional view of a key portion of a microwave plasma generator according to the embodiment of the present invention. FIG. 2 is a magnified sectional view of a launcher portion in the above-described embodiment. FIG. 3 is a magnified diagram of a part of a second conductor plate of the above-described launcher. FIG. 4 is a plan view of the above-described device and a block diagram of a driving source.

The plane configuration of the device in the present embodiment and a driving circuit are shown in FIG. 4. A 2.45-GHz microwave oscillator (magnetron) is used as a microwave source 9 to generate an excitation microwave. This microwave source 9 is driven by a microwave source driving device 15. The control signal (containing the negative feedback signal) 15a is transmitted to the microwave source driving device 15 such that the magnetron can be intermittently driven, if necessary. A carrier gas is supplied from a discharge gas source, although not shown in the drawing, to a plasma generation vacuum vessel 1. A coaxial waveguide 3 introduces the excitation microwave into the above-described vessel 1.

As shown in FIG. 2, a parallel plate launcher 2 includes a first conductor plate 21 connected to an outer conductor 31 of the above-described coaxial waveguide 3, a quartz dielectric plate 25, and a second conductor plate 22. Seal rings 23 and 24 are disposed between the first conductor plate 21 and the quartz dielectric plate 25.

The above-described second conductor plate 22 is connected to a central conductor 32 of the above-described coaxial waveguide 3 and is provided with a plurality of openings 22a to emit evanescent microwaves 26 . . . 26 into the above-described vacuum vessel 1 (refer to FIG. 3). The quartz dielectric plate 25 disposed between the first conductor plate 21 and the second conductor plate 22 constitutes the parallel plate launcher (or dielectric transmission-line microwave launcher) 2 including a resonant cavity.

A support device (substrate stage 4) to support a work is disposed at the position facing the second conductor plate 22 of the above-described launcher in the above-described vacuum vessel 1. In the present embodiment, the substrate stage 4 is supported by a shaft 41, and can be moved vertically in the above-described vacuum vessel 1. The above-described coaxial waveguide 3 is hermetically coupled to the above-described vacuum vessel 1 and supports the above-described launcher 2. A relative distance between the work (not shown) on the substrate stage 4 and the above-described launcher 2 can be adjusted by making at least one of the above-described coaxial waveguide 3 and the substrate stage 4 possible to hermetically move relative to the vessel. A probe 6 is inserted into the vacuum vessel 1 to obtain the information about the plasma in the inside.

In the present embodiment, the above-described vacuum vessel 1 is a cylindrical vessel, the above-described coaxial waveguide 3 is disposed along the center line of the above-described vessel, and the outline of the first conductor plate 21 of the above-described launcher 2 is slightly smaller than the inner diameter of the above-described vessel 1, such that homogeneous plasma is generated in the vessel. A cylindrical portion extending in the direction of the above-described second conductor plate 22 is disposed on the perimeter of the first conductor plate 21 of the above-described launcher 2, and a ring-shaped gap to emit an evanescent microwave is disposed between the bottom end edge of the above-described cylindrical portion and the perimeter of the above-described second conductor plate 22. This gap is intended for generating plasma up to the vicinity of the wall surface of the vessel, and it is certainly expected that adequate plasma can be generated by the evanescent microwaves from the plurality of openings.

In this device, the temperature of, in particular, the launcher portion is increased during the continuous operation. However, a preferable temperature state can be maintained by generating a pulse-modulation output from a microwave source driving device 15 so as to intermittently drive the above-described microwave source 9.

More detailed configuration and operation will be described below. The microwave source 9 formed from the magnetron oscillates at 2.45 GHz, and an oscillation output is passed through a rectangular waveguide circuit, and is transmitted to a waveguide 11 of a transducer terminated by a short-circuit plate 10. An isolator (not shown), a directional coupler 8, and a tuner 7 are disposed along the path from the microwave source 9 to the waveguide 11 of the transducer.

The microwave (TEM₀₀) subjected to coaxial transformation in the waveguide 11 of the transducer becomes in a resonance mode (TMₘₙ) in a resonator portion, and the evanescent waves 26 are emitted from the openings 22a into the vacuum vessel 1. In the present embodiment, expected modes are TM₄₂, TM₇₁, TM₂₃, and TM₀₄.

The vacuum vessel 1 is in the shape of a cylinder of 250 mm in diameter and 500 mm in height.

The diameter of the first conductor plate of the parallel plate launcher 2 was assumed to be D₁(=240 mm) and the diameter of the second conductor plate was assumed to be D₂. The diameter of the opening of the second conductor plate of the parallel plate launcher 2 was assumed to be dₕ, and the distance between adjacent openings of the second conductor plate was assumed to be dₛ.

Experiments were conducted on the following four types of launcher 2, where the diameter D₁(=240 mm) of the first conductor plate of the parallel plate launcher 2 and the thickness of the quartz dielectric 25 of 8 mm were common to all examples.
D₁=240 mm, D₂=220 mm, dₕ=1 mm, and dₛ=1.5 mm (1)
D₁=240 mm, D₂=220 mm, dₕ=8 mm, and dₛ=12 mm (2)
D₁=240 mm, D₂=230 mm, dₕ=1 mm, and dₛ=1.5 mm (3)
D₁=240 mm, D₂=230 mm, dₕ=8 mm, and dₛ=12 mm (4)

As for the electric discharge condition of the plasma generation, the microwave incident power was 700 W, the reflection power was 20 W, and argon, oxygen, and the like were used as the electrical discharge gases. The gas pressure was 10 to 20 Pa (pascal), and the gas flow rate was 100 to 200 sccm.

The microwave propagates through the coaxial waveguide 3 and propagates through the quartz plate 25. In the above-described cases (1) and (2), there is the leakage radiation from both the plurality of openings and the periphery portion. In the above-described cases (3) and (4) where the quartz plate occupies up to the inner wall of the perimeter metal of the surrounding upper conductor plate 21, and is completely sealed with the lower conductor plate 22, a resonator structure is constructed. Therefore, the electromagnetic field in the mode satisfying the resonance condition is distributed in the inside of the quartz, and it is believed that plasma is generated by only the leakage from the holes in the punching plate. The plasma discharge was observed all over the launcher surface at a microwave power of 500 W and a gas pressure of about 150 Pa. In each of the above-described examples, excellent plasma discharge and diffusion were observed.

As described above, the microwave plasma generator according to the present invention includes the parallel plate launcher in which the resonant cavity is constructed from the first conductor plate connected to the outer conductor of the above-described coaxial waveguide, the dielectric plate, and the second conductor plate connected to the central conductor of the above-described coaxial waveguide and provided with the plurality of openings to emit the evanescent microwaves into the above-described vacuum vessel.

Since a structure in which the microwave introduction portion is disposed in the vacuum vessel is adopted, it becomes unnecessary to use a quartz plate as a seal material of the vacuum vessel or a window for the microwave. Although the quartz plate is expensive, the vacuum vessel can be produced inexpensively with no restriction due to the quartz plate.

The evanescent microwaves are directly and efficiently introduced into the vessel from the openings of the second conductor plate provided with the plurality of openings. The quartz plate serves as a dielectric in the inside of the resonator, and the microwaves act on the gas without being interfered by the quartz plate. Therefore, the efficiency of plasma excitation can be increased than those of known devices. It is unnecessary to rely on the ECR system, and the diameter can be increased through the microwave propagation.

In the microwave plasma generator according to the present invention, the above-described coaxial waveguide is hermetically coupled to the above-described vacuum vessel and supports the above-described launcher. The support device to support a work is disposed at the position facing the second conductor plate of the above-described launcher, and a relative distance between the above-described support device and the above-described launcher is adjustable. Therefore, there is an advantage that the plasma density at the work can be adjusted.

Since the propagation wavelength of the microwave can be decreased correspondingly to a relative dielectric constant of the dielectric by applying the dielectric transmission-line system to the launcher, the number of modes of the electromagnetic field distribution in the radius direction is increased, and there is an advantage that the homogeneity of the spatial distribution of the plasma generated can be improved as compared with that in the case where no dielectric is used.

According to the examples of the present invention, it was ascertained that stable plasma was able to be generated by disposing a plurality of openings of about 1 to 8 mm in diameter in the vacuum vessel 1 which was a cylindrical vessel of about 250 mm in diameter and about 500 mm in height. This size of the opening can be applied to a vacuum vessel having a larger diameter, and the electromagnetic field distribution can be made more homogeneous.

Various modifications within the scope of the present invention can be applied to the embodiment described above in detail. For example, a water-cooling system of the launcher portion is introduced to prevent the overheating of the quartz plate, thereby a plasma generator having a larger output can be provided. The resonance type launcher is shown in the embodiment. However, the radiation from the periphery in a mode other than the evanescent mode can coexist.

What is claimed is:

1. A microwave plasma generator comprising:
a microwave source to generate an excitation microwave;
a discharge gas source;
a plasma generation vacuum vessel to be supplied with a gas from the discharge gas source;
a coaxial waveguide to introduce the excitation microwave into the vessel; and
a parallel plate launcher in which a resonant cavity is constructed from a first conductor plate connected to an outer conductor of the coaxial waveguide, a dielectric plate, and a second conductor plate connected to a central conductor of the coaxial waveguide and provided with a plurality of openings to emit evanescent microwaves into the vacuum vessel, wherein
the plurality of openings are circular openings,
the space in the coaxial waveguide is isolated from the space in the vessel by an interplanar O-ring disposed between the first conductor plate and the dielectric plate, and
the coaxial waveguide is constructed while being hermetically and slidably supported by the vacuum vessel.

2. The microwave plasma generator according to claim 1, wherein the coaxial waveguide supports the launcher in the vacuum vessel and is hermetically and slidably coupled to the vacuum vessel, a support device to support a work is disposed at the position facing the second conductor plate of the launcher, and a relative distance between the support device and the launcher is adjustable.

3. The microwave plasma generator according to claim 1, wherein the vacuum vessel is a cylindrical vessel, the coaxial waveguide can be moved along the center line of the vessel, and the outline of the first conductor plate of the launcher is slightly smaller than the inner diameter of the vessel.

4. The microwave plasma generator according to claim 1, wherein a cylindrical portion extending in the direction of the second conductor plate is disposed on the perimeter of the first conductor plate of the launcher, and a microwave emission gap is disposed between the bottom end edge of the cylindrical portion and the perimeter of the second conductor plate.

5. The microwave plasma generator according to claim 1, wherein an output to pulse-modulate the microwave source is generated by a microwave source driving device, and intermittent driving is effected.
